(19) United States
(12) Patent Application Publication
(10) Pub. No.: US 2014/0022715 A1
(43) Pub. Date: Jan. 23, 2014

(54) TOP CHASSIS AND DISPLAY DEVICE HAVING THE SAME

(71) Applicant: SAMSUNG DISPLAY CO., LTD, Yongin-City (KR)

(72) Inventors: Jae Joong Kim, Yongin-City (KR); Chang Jin Im, Yongin-City (KR); An Ho Jee, Yongin-City (KR); Seok Hoon Yoon, Yongin-City (KR); Young Hoon Lee, Yongin-City (KR)

(73) Assignee: Samsung Display Co., Ltd, Yongin-City (KR)

(21) Appl. No.: 13/860,513

(22) Filed: Apr. 10, 2013

(30) Foreign Application Priority Data
Jul. 23, 2012 (KR) 10-2012-0080012

(51) Int. Cl. H05K 5/00

(52) U.S. Cl. CPC H05K 5/0017
USPC 361/679.01

(57) ABSTRACT

A display device includes a display panel comprising a pixel region; a protective film on the display panel; and a top chassis on the display panel and defining a first open surface which exposes the pixel region and a second open surface which protrudes from an end of the first open surface.

This application claims priority from Korean Patent Application No. 10-2012-0080012 filed on Jul. 23, 2012 in the Korean Intellectual Property Office, the disclosure of which is incorporated herein by reference in its entirety.

### BACKGROUND

1. Field

The present invention relates to a top chassis and a display device having the same.

2. Description of the Related Art

Various display devices such as liquid crystal displays (LCDs) and organic light-emitting diode (OLED) displays include a display panel which includes a pixel region. High surface quality of the pixel region of the display panel is desired in all industries. To improve the surface quality of the pixel region, it is important to prevent the display panel from being damaged during the manufacture of a display device and after the completion of the display device.

One way of preventing the display panel from being damaged during the process of manufacturing the display device is to perform the process of manufacturing the display device after a protective film is placed on the surface of the display panel. The protective film placed on the surface of the display panel absorbs shocks that can be applied to the display panel during the process of manufacturing the display panel. Thus, the protective film may be damaged instead of the display panel.

On occasion, after a top chassis is coupled to the display panel, it is not easy to remove the protective film since a base plate of the top chassis is placed on edges of the protective film. Therefore, the protective film is removed before the top chassis is coupled to the display panel, and another protective film is attached onto the top chassis after the completion of the display device in order to prevent the damage of the display panel. The protective film can be arbitrarily removed by a consumer.

### SUMMARY

Aspects of the present invention provide a display device which is structured to allow a protective film to be removed easily.

Aspects of the present invention also provide a top chassis for a display device, which is structured to allow a protective film to be removed easily.

However, aspects of the present invention are not restricted to the one set forth herein. The above and other aspects of the present invention will become more apparent to one of ordinary skill in the art to which the present invention pertains by referencing the detailed description of the present invention given below.

According to an aspect of the present invention, there is provided a display device comprising a display panel comprising a pixel region, a protective film on the display panel, and a top chassis on the display panel and defining a first open surface which exposes the pixel region and a second open surface which protrudes from an end of the first open surface.

According to another aspect of the present invention, there is provided a display device comprising a display panel comprising a pixel region, a protective film on the display panel, and a top chassis on the display panel, defining an open surface which exposes the pixel region, and comprising an openable surface which protrudes from an end of the open surface.

According to another aspect of the present invention, there is provided a top chassis comprising a base plate defining a first open surface which exposes a pixel region and a second open surface which protrudes from an end of the first open surface.

### BRIEF DESCRIPTION OF THE DRAWINGS

The above and other aspects and features of the present invention will become more apparent by describing in detail exemplary embodiments thereof with reference to the attached drawings, in which:

FIG. 1 is an exploded perspective view of a display device according to an embodiment of the present invention;

FIG. 2 is a perspective view of a top chassis for the display device shown in FIG. 1;

FIG. 3 is a plan view of the display device shown in FIG. 1;

FIG. 4 is a cross-sectional view of the display device taken along the line IV-IV′ of FIG. 3;

FIG. 5 is a plan view of a display device according to another embodiment of the present invention;

FIG. 6 is a cross-sectional view of the display device taken along the line VI-VI′ of FIG. 5;

FIG. 7 is a plan view of a display device according to another embodiment of the present invention;

FIG. 8 is a cross-sectional view of the display device taken along the line VIII-VIII′ of FIG. 7;

FIG. 9 is a plan view of a display device according to another embodiment of the present invention;

FIG. 10 is a plan view of a display device according to another embodiment of the present invention;

FIG. 11 is a cross-sectional view of the display device taken along the line X-X′ of FIG. 10;

FIG. 12 is a plan view of a display device according to another embodiment of the present invention;

FIG. 13 is a plan view of a modified embodiment of the display device shown in FIG. 12;

FIG. 14 is a plan view of a display device according to another embodiment of the present invention; and

FIG. 15 is a cross-sectional view of the display device taken along the line XV-XV′ of FIG. 14.

### DETAILED DESCRIPTION

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Thus, in some embodiments, well-known structures and devices are not shown in order not to obscure the description of the invention with unnecessary detail. Like numbers refer to like elements throughout. In the drawings, the thickness of layers and regions are exaggerated for clarity.

It will be understood that when an element or layer is referred to as being “on,” or “connected to” another element or layer, it can be directly on or connected to the other element or layer or intervening elements or layers may be present. In contrast, when an element is referred to as being “directly on” or “directly connected to” another element or layer, there are no intervening elements or layers present. As used herein, the term “and/or” includes any and all combinations of one or more of the associated listed items.

Spatially relative terms, such as “below,” “beneath,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

Embodiments described herein will be described referring to plan views and/or cross-sectional views by way of ideal schematic views of the invention. Accordingly, the exemplary views may be modified depending on manufacturing technologies and/or tolerances. Therefore, the embodiments of the invention are not limited to those shown in the views, but include modifications in configuration formed on the basis of manufacturing processes. Therefore, regions exemplified in figures have schematic properties and shapes of regions shown in figures exemplify specific shapes of regions of elements and not limit aspects of the invention.

Hereinafter, embodiments of the present invention will be described with reference to the attached drawings.

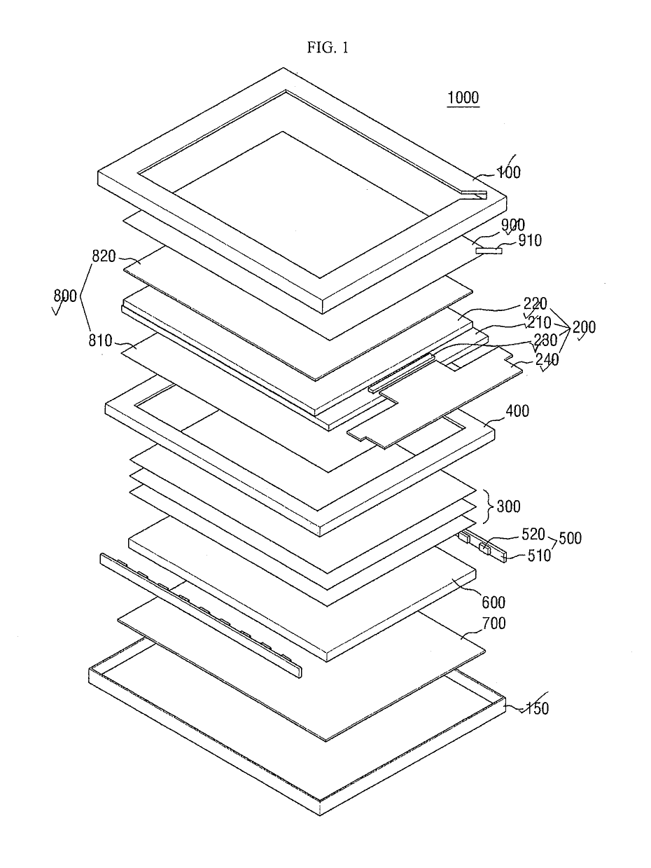

FIG. 1 is an exploded perspective view of a display device 1000 according to an embodiment of the present invention. Referring to FIG. 1, the display device 1000 includes a display panel 200, a protective film 900, and a top chassis 100. The display device 1000 may further include a polarizing film 800, a light source assembly, and a bottom chassis 150.

The display panel 200 is a panel that displays images. Examples of the display panel 200 include a liquid crystal display (LCD) panel, an electrophoretic display panel, an organic light-emitting diode (OLED) panel, a light-emitting diode (LED) panel, an inorganic electroluminescent (EL) display panel, a field emission display (FED) panel, a surface-conduction electron-emitter display (SED) panel, a plasma display panel (PDP), and a cathode ray tube (CRT) display panel. A case where the display device 1000 according to the current embodiment is an LCD will be described below as an example. In addition, a case where the display panel 200 is an LCD panel will be described as an example. However, the display device 1000 and the display panel 200 according to the present invention are not limited to these examples, and various types of display devices and display panels can be used as the display device 1000 and the display panel 200.

The display panel 200 may include a first substrate 210, a second substrate 220 which faces the first substrate 210, a liquid crystal layer, and a flexible circuit board 240 which is attached to the first substrate 210.

The first substrate 210 may include a pixel region and a non-pixel region. The pixel region of the first substrate 210 is where images are displayed, and the non-pixel region of the first substrate 210 is where no images are displayed. A driver 230 may be formed in the non-display region of the first substrate 210 to transmit various signals (such as a driving signal) required to display an image in the pixel region.

The pixel region of the first substrate 210 may be overlapped by the second substrate 220. However, the non-pixel region of the first substrate 210 may be exposed without being overlapped by the second substrate 220.

The second substrate 220 may face the first substrate 210. The liquid crystal layer may be located between the first substrate 210 and the second substrate 220. A sealing member such as a sealant may be placed between the first and second substrates 210 and 220 along the periphery of the first and second substrates 210 and 220, thereby bonding the first and second substrates 210 and 220 together.

The first substrate 210 and the second substrate 220 may be rectangular parallelepipeds. Although the first substrate 210 and the second substrate 220 are illustrated in FIG. 1 as being rectangular parallelepipeds for ease of description, their shape can vary according to the shape of the display panel 200.

The flexible circuit board 240 may be attached to the first substrate 210 and may output various signals to the driver 230 of the non-pixel region.

The polarizing film 800 may include a first polarizing film 810 and a second polarizing film 820. Each of the first polarizing film 810 and the second polarizing film 820 may be located directly on the display panel 200. Specifically, the first polarizing film 810 may be on a first surface of the display panel 200, and the second polarizing film 820 may be on a second surface of the display panel 200 which is opposite the first surface of the display panel 200. The first and second surfaces of the display panel 200 may be opposite surfaces which face each other. The first polarizing film 810 and the second polarizing film 820 may be rectangular parallelepipeds. Although the first polarizing film 810 and the second polarizing film 820 are illustrated in FIG. 1 as being rectangular parallelepipeds for ease of description, their shape can vary according to the shape of the display panel 200.

The protective film 900 may be on the second polarizing film 820 to protect the display panel 200 and the second polarizing film 820. Specifically, the protective film 900 may be provided to prevent the display panel 200 and the second polarizing film 820 from being damaged during a process of manufacturing the display device 1000. Also, the protective film 900 may be provided to protect the display panel 200 and the second polarizing film 820 from the external environment after the process of manufacturing the display device 1000. A film detaching member 910 may be attached to an end of the protective film 900. The film detaching member 910 may be used to detach the protective film 900 from the second polarizing film 820. The film detaching member 910 will be described later.

The light source assembly may be located under the display panel 200. The light source assembly may include light source units 500, a light guide plate 600, a reflective sheet 700, one or more optical sheets 300, and a mid frame 400. Each of the light source units 500 includes light sources 520 which emit light and a circuit board 510 on which the light sources 520 are placed. The light guide plate 600 guides light emitted from the light source unit 500. The reflective sheet 700 is located under the light guide plate 600 and changes the path of light proceeding downward from the light guide plate 600. The optical sheets 300 are on the light guide plate 600 and modulate optical characteristics of output light. The mid frame 400 accommodates the light source units 500, the light guide plate 600, the reflective sheet 700, and the optical sheets 300.

In FIG. 1, an edge-type light source assembly in which the light sources 520 are located on sides of the light guide plate 600 is illustrated as an example of the light source assembly. However, the light source assembly is not limited to the edge-type light source assembly. A direct-type light source assembly in which the light sources 520 are located under the light guide plate 600 is also applicable as the light source assembly.

The bottom chassis 150 may accommodate the optical sheets 300, the light guide plate 600, the light source units 500, and the reflective sheet 700. The bottom chassis 150 may be made of a conductive material such as metal.

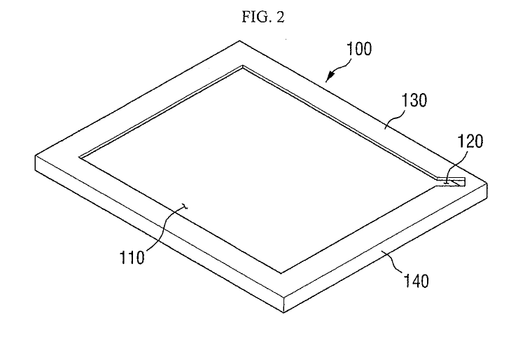

The display device 1000 may further include the top chassis 100 which covers edges of the display panel 200 and surrounds side surfaces of the display panel 200 and the light source assembly. The top chassis 100 for the display device 1000 according to the current embodiment will now be described in more detail with reference to FIG. 2.

FIG. 2 is a perspective view of the top chassis 100 for the display device 1000 shown in FIG. 1.

The top chassis 100 includes a base plate 130 and a plurality of sidewalls 140 which extends from the base plate 130. The base plate 130 defines a first open surface 110 which exposes the pixel region of the display panel 200 and a second open surface 120 which protrudes from an end of the first open surface 110. Each of the sidewalls 140 may extend from the base plate 130 in a direction, for example, in a vertical direction. Although not shown in FIG. 2, at least one of the sidewalls 140 may include a coupling portion coupled to the mid frame 400.

In FIG. 2, the first open surface 110 is illustrated as being rectangular for ease of description. However, the shape of the first open surface 110 is not limited to the rectangular shape. The first open surface 110 can also have a circular shape or another polygonal shape. In addition, in FIG. 2, an end of the first open surface 110 from which the second open surface 120 protrudes is a vertex of a rectangle. However, the present invention is not limited thereto. The end of the first open surface 110 from which the second open surface 120 protrudes can also be a side of the rectangle or a portion of a side of the rectangle. In addition, edges of the second open surface 120 are illustrated in FIG. 2 as being straight for ease of description. However, the present invention is not limited thereto. The edges of the second open surface 120 can also be curved.

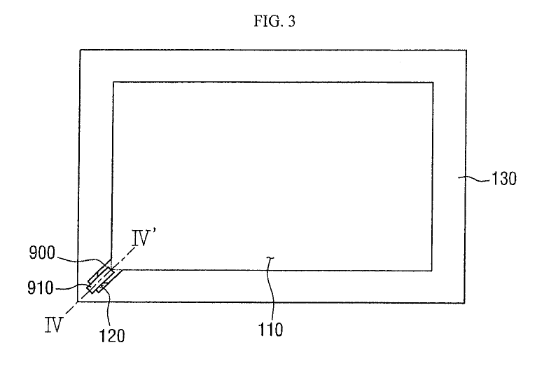

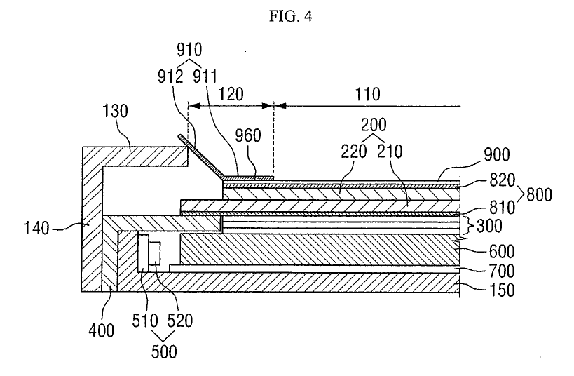

The top chassis 100, the protective film 900 and the film detaching member 910 will now be described in more detail with reference to FIG. 3 which is a plan view of the display device 1000 shown in FIG. 1 and FIG. 4 which is a cross-sectional view of the display device 1000 taken along the line IV-IV′ of FIG. 3.

Referring to FIG. 4, the top chassis 100 may be on the display panel 200 and the protective film 900. The top chassis 100 is on the edges of the display panel 200, that is, the non-pixel region and side surfaces of the mid frame 400. The base plate 130 of the top chassis 100 defines the first open surface 110 which exposes the pixel region and the second open surface 120 which protrudes from an end of the first open surface 110. In the current embodiment, the first open surface 110 is shaped like a rectangle, and an end of the first open surface 110 is a vertex of the rectangle. In addition, the second open surface 120 extends from the open surface 110 with a uniform width. In the current embodiment, the second open surface 120 not only exposes the whole of an end of the protective film 900 which faces the second open surface 120 but also extends further in a direction in which it protrudes from the first open surface 110.

The display device 1000 may further include the film detaching member 910. The film detaching member 910 may be attached to the protective film 900 and may be at least partially exposed through the second open surface 120.

Specifically, the film detaching member 910 may include an adhering portion 911 and a protruding portion 912. The adhering portion 911 of the film detaching member 910 may be attached to an end of the protective film 900. Here, the adhering portion 911 may be attached onto the protective film 900 which faces the second open surface 120. An adhesive layer 960 may be formed between the adhering portion 911 of the film detaching member 910 and the protective film 900. The protruding portion 912 of the film detaching member 910 may extend from the adhering portion 911 in the direction in which the second open surface 120 protrudes. In addition, the protruding portion 912 may extend upward from an end of the adhering portion 911 to contact the base plate 130 of the top chassis 100. Here, the protruding portion 912 and the adhering portion 911 may form an obtuse angle. In addition, at least a portion of the protruding portion 912 may protrude further than a surface of the top chassis 100. Although not shown in FIG. 4, at least a portion of the protruding portion 912 may be attached to the top chassis 100, and an adhesive layer 970 may be formed between the portion of the protruding portion 912 and the top chassis 100.

Since the display device 1000 according to the current embodiment includes the second open surface 120 defined by the top chassis 100, the film detaching member 910 attached to an end of the protective film 900 is exposed, and the protective film 900 can be easily removed using the protruding portion 912 of the film detaching member 910. That is, the protective film 900 used to prevent the display panel 200 from being damaged during the process of manufacturing the display device 1000 does not need to be removed before the top chassis 100 and the display panel 200 are coupled to each other. Instead, the protective film 900 can be arbitrarily removed by a consumer after the completion of the display device 1000. Therefore, a process of removing the protective film 900 during the manufacture of the display device 1000 and a process of attaching another protective film 900 onto the top chassis 100 after the completion of the display device 1000 can be omitted. Accordingly, this can reduce the time required to manufacture the display device 1000. Furthermore, since it is not necessary to attach another protective film 900 onto the top chassis 100, the material cost of the display device 1000 can be saved.

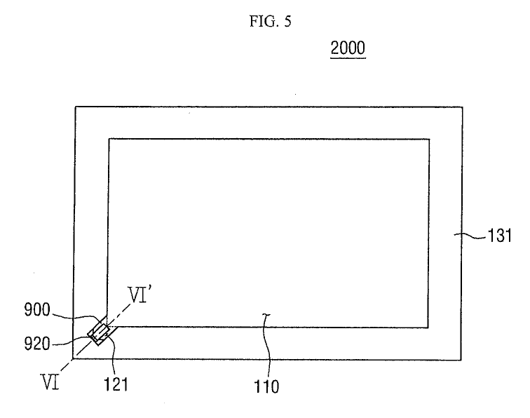

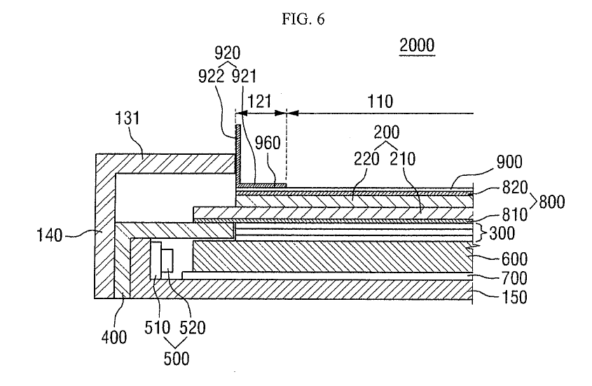

FIG. 5 is a plan view of a display device 2000 according to another embodiment of the present invention. FIG. 6 is a cross-sectional view of the display device 2000 taken along the line VI-VI′ of FIG. 5. For simplicity, elements substantially identical to those of the display device 1000 shown in FIGS. 1 through 4 are indicated by like reference numerals, and thus a repetitive description thereof will be omitted.

Referring to FIGS. 5 and 6, a base plate 131 of a top chassis defines a first open surface 110 which exposes a pixel region and a second open surface 121 which protrudes from an end of the first open surface 110. The second open surface 121 may protrude from an end of the first open surface 110 only to a distance at which it exposes the whole of an end of a protective film 900 which faces the second open surface 121. Here, when the second open surface 121 protrudes only to a distance at which it exposes the whole of an end of the protective film 900, a longitudinal section of the end of the protective film 900 which faces the second open surface 121 is aligned with a longitudinal section of the second open surface 121, as shown in FIGS. 5 and 6. The second open surface 121 is substantially identical to the second open surface 120 of FIGS. 1 through 4 except that the second open surface 121 protrudes from an end of the first open surface 110 only to a distance at which it exposes the whole of an end of the protective film 900 which faces the second open surface 121, and thus a repetitive description thereof will be omitted.

In addition, referring to FIGS. 5 and 6, the display device 2000 may further include a film detaching member 920 which is attached to the protective film 900 and is at least partially exposed through the second open surface 121. The film detaching member 920 may include an adhering portion 921 and a protruding portion 922. The protruding portion 922 and the adhering portion 921 may form a right angle. The film detaching member 920 is substantially identical to the film detaching member 910 of FIGS. 1 through 4 except that the protruding portion 922 and the adhering portion 921 form a right angle, and thus a repetitive description thereof will be omitted.

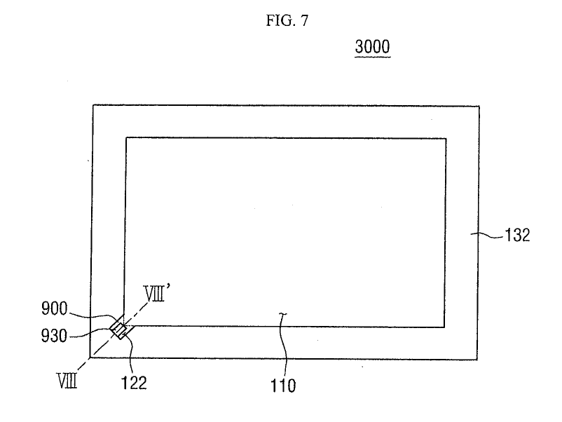

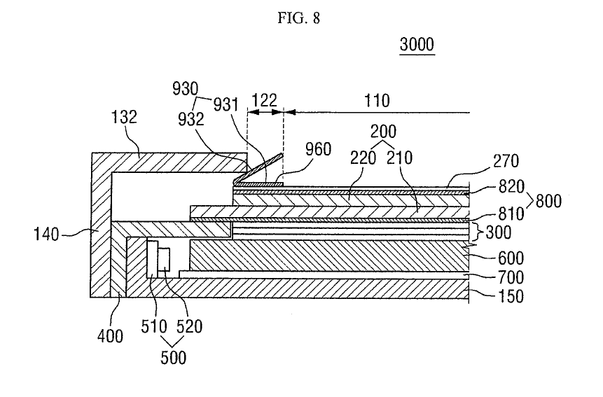

FIG. 7 is a plan view of a display device 3000 according to another embodiment of the present invention. FIG. 8 is a cross-sectional view of the display device 3000 taken along the line VIII-VIII′ of FIG. 7. For simplicity, elements substantially identical to those of the display device 1000 shown in FIGS. 1 through 4 are indicated by like reference numerals, and thus a repetitive description thereof will be omitted.

Referring to FIGS. 7 and 8, a base plate 132 of a top chassis defines a first open surface 110 which exposes a pixel region and a second open surface 122 which protrudes from an end of the first open surface 110. The second open surface 122 may exposes only part of an end of a protective film 900 which faces the second open surface 122. The second open surface 122 is substantially identical to the second open surface 120 of FIGS. 1 through 4 except that the second open surface 122 exposes only part of an end of the protective film 900 which faces the second open surface 122, and thus a repetitive description thereof will be omitted.

In addition, referring to FIGS. 7 and 8, the display device 3000 may further include a film detaching member 930 which is attached to the protective film 900 and is at least partially exposed through the second open surface 122. The film detaching member 930 may include an adhering portion 931 and a protruding portion 932. The protruding portion 932 and the adhering portion 931 may form an acute angle. The film detaching member 930 is substantially identical to the film detaching member 910 of FIGS. 1 through 4 except that the protruding portion 932 and the adhering portion 931 form an acute angle, and thus a repetitive description thereof will be omitted.

As described above, in the display devices 1000 through 3000 according to the various embodiments of the present invention, an angle formed by the adhering portion 911, 921 or 931 and the protruding portion 912, 922 or 932 of the film detaching member 910, 920 or 930 may vary according to the distance to which the second open surface 120, 121 or 122 defined by the top chassis 100 protrudes. Therefore, the top chassis 100 and the film detaching members 910 through 930 of the display devices 1000 through 3000 according to the various embodiments of the present invention may be structured flexibly to meet various design needs and/or the needs for the processing environment.

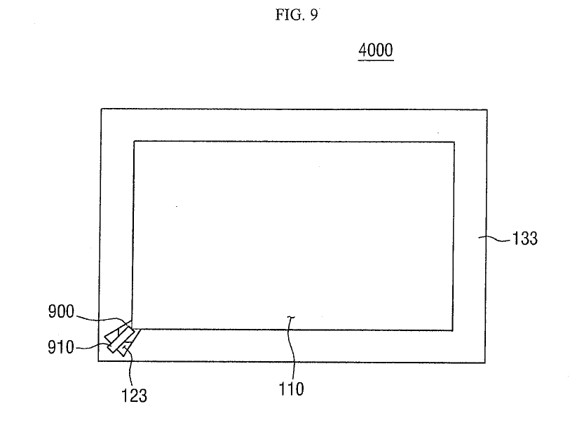

FIG. 9 is a plan view of a display device 4000 according to another embodiment of the present invention. For simplicity, elements substantially identical to those of the display device 1000 shown in FIG. 3 are indicated by like reference numerals, and thus a repetitive description thereof will be omitted.

Referring to FIG. 9, a base plate 133 of a top chassis defines a first open surface 110 which exposes a pixel region and a second open surface 123 which protrudes from an end of the first open surface 110. A width of the second open surface 123 may be reduced toward the first open surface 110. The second surface 123 is substantially identical to the second open surface 120 of FIGS. 1 through 4 except that the width of the second open surface 123 is reduced toward the first open surface 110, and thus a repetitive description thereof will be omitted.

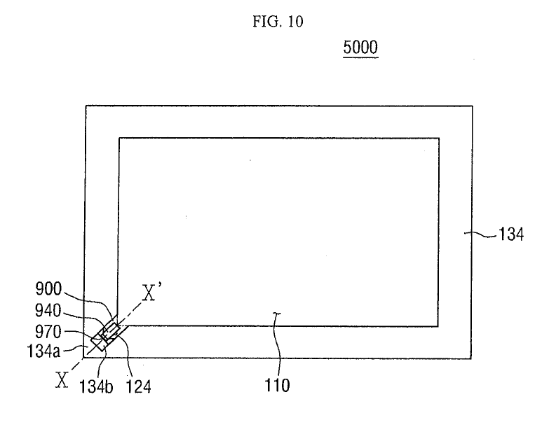

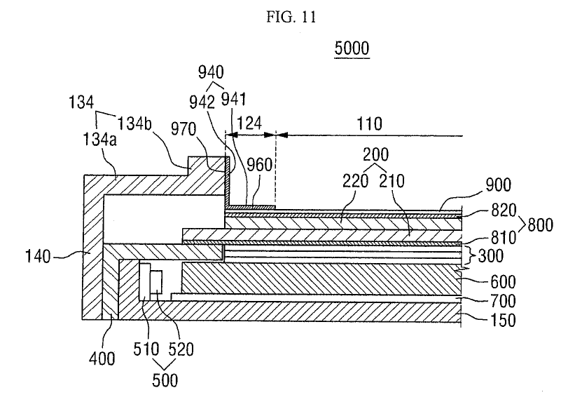

FIG. 10 is a plan view of a display device 5000 according to another embodiment of the present invention. FIG. 11 is a cross-sectional view of the display device 5000 taken along the line X-X′ of FIG. 10. For simplicity, elements substantially identical to those of the display device 1000 shown in FIGS. 1 through 4 are indicated by like reference numerals, and thus a repetitive description thereof will be omitted.

Referring to FIGS. 10 and 11, a base plate 134 of a top chassis defines a first open surface 110 which exposes a pixel region and a second open surface 124 which protrudes from an end of the first open surface 110. The base plate 134 may include a flat plate 134a ; and a protruding plate 134b protruding upward from a region of the flat plate 134a ; which is adjacent to the second open surface 124. Specifically, the protruding plate 134b may be formed on the flat plate 134a ; to be adjacent to a longitudinal section of the second open surface 124. The protruding plate 134b may be shaped like a rectangular parallelepiped plate, and a cross section of the protruding plate 134b may be shaped like a quadrilateral. However, the present invention is not limited thereto, and the protruding plate 134b and the cross section of the protruding plate 134b can have various shapes. The base plate 134 is substantially identical to the base plate 130 of FIGS. 1 through 4 except that the base plate 134 includes the flat plate 134a ; and the protruding plate 134b, and thus a repetitive description thereof will be omitted.

In addition, referring to FIGS. 10 and 11, the display device 5000 may further include a film detaching member 940 which is attached to s protective film 900 and is at least partially exposed through the second open surface 124. The film detaching member 940 may include an adhering portion 941 and a protruding portion 942. The protruding portion 942 and the adhering portion 941 may form a right angle. An end of the protruding portion 942 may be attached to side surfaces of the flat plate 134a ; and the protruding plate 134b of the base plate 134, and a height of a longitudinal section of the protruding portion 942 may be equal to or smaller than a height of a top surface of the protruding plate 134b. In one embodiment, an adhesive layer 970 may be formed between the end of the protruding portion 942 and the side surfaces of the flat plate 134a ; and the protruding plate 134b of the base plate 134. The film detaching member 940 is substantially identical to the film detaching member 910 of FIGS. 1 through 4 except that the protruding portion 942 and the adhering portion 941 form a right angle, that an end of the protruding portion 942 is attached to the side surfaces of the flat plate 134a ; and the protruding plate 134b of the base plate 134, that a height of a top end of the protruding portion 942 is equal to or smaller than that of the top surface of the protruding plate 134b and that the adhesive layer 970 is formed between the end of the protruding portion 942 and the side surfaces of the flat plate 134a ; and the protruding plate 134b of the base plate 134, and thus a repetitive description thereof will be omitted.

In the display device 5000 according to the current embodiment of the present invention, the protruding portion 942 of the film detaching member 940 does not protrude onto the base plate 134 but is fixed to the side surface of the protruding plate 134b. Thus, it may be easy to handle the display device 5000.

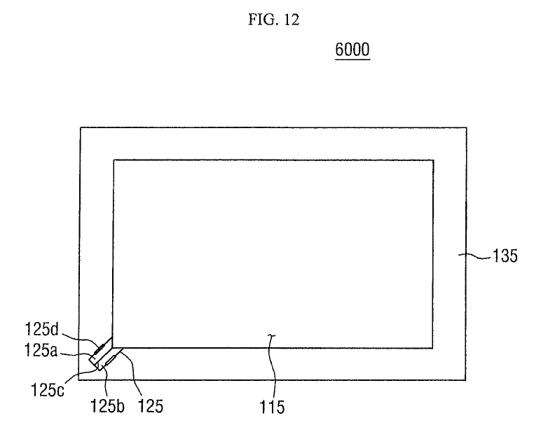

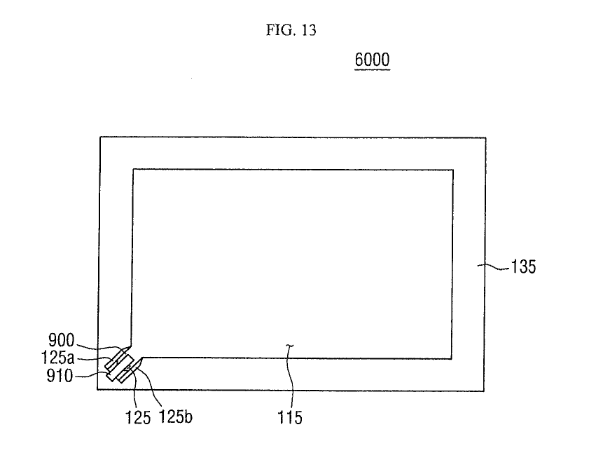

FIG. 12 is a plan view of a display device 6000 according to another embodiment of the present invention. FIG. 13 is a plan view of a modified embodiment of the display device 6000 shown in FIG. 12. For simplicity, elements substantially identical to those of the display device 1000 shown in FIG. 3 are indicated by like reference numerals, and thus a repetitive description thereof will be omitted.

Referring to FIGS. 12 and 13, the display device 6000 according to the current embodiment includes a display panel which includes a pixel region, a protective film 900 which is on the display panel, and a top chassis which is on the display panel, defines an open surface 115 exposing the pixel region, and includes an openable surface 125 protruding from an end of the open surface 115.

A base plate 135 of the top chassis may define the open surface 115 which exposes the pixel region and include the openable surface 125 which protrudes from an end of the open surface 115. The openable surface 125 may include one or move cover portions. The cover portions may be formed on both sides of a centerline 125c which extends from an end of the open surface 115. That is, a first cover portion 125a may be formed on a side of the centerline 125c, and a second cover portion 125b may be formed on the other side of the centerline 125c. Each of the first and second cover portions 125a and 125b may further include a hinge portion 125d. The first and second cover portions 125a and 125b may be opened in both directions from the centerline 125c.

In addition, referring to FIGS. 12 and 13, the display device 6000 may further include a film detaching member 910 which is attached to the protective film 900. The film detaching member 910 may be disposed under the openable surface 125. Specifically, referring to FIG. 12, the film detaching member 910 may not be exposed when the openable surface 125 is closed. Referring to FIG. 13, the film detaching member 910 may be exposed when the openable surface 125 is open. The film detaching member 910 is substantially identical to the film detaching member 910 of FIGS. 1 through 4 except that the film detaching member 910 is or is not exposed according to whether the openable surface 125 is open or closed, and thus a repetitive description thereof will be omitted.

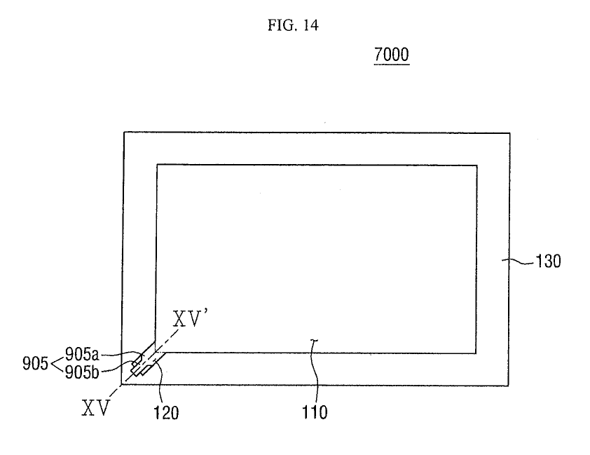

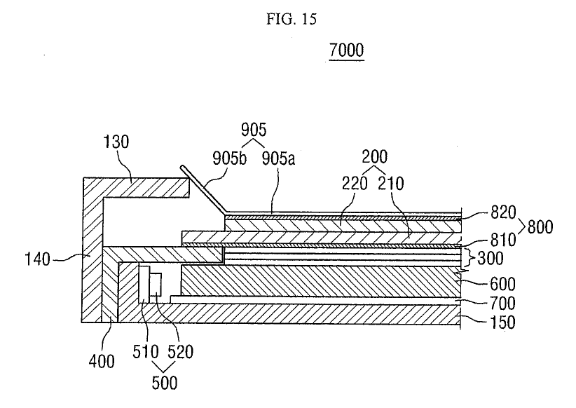

FIG. 14 is a plan view of a display device 7000 according to another embodiment of the present invention. FIG. 15 is a cross-sectional view of the display device 7000 taken along the line XV-XV′ of FIG. 14. For simplicity, elements substantially identical to those of the display device 1000 shown in FIGS. 1 through 4 are indicated by like reference numerals, and thus a repetitive description thereof will be omitted.

Referring to FIGS. 14 and 15, a film detaching member may be integrated with a protective film 905. That is, the protective film 905 may include a panel protecting portion 905a and a film detaching portion 905b which is integrated with the panel protecting portion 905a and protrudes from a surface of the panel protecting portion 905a.

Embodiments of the present invention provide at least one of the following characteristics.

First of all, a process of removing a protective film used to prevent a display panel from being damaged during a process of manufacturing a display device and a process of attaching another protective film onto a top chassis can be omitted. Accordingly, the time required to manufacture the display device can be reduced.

Furthermore, since it is not necessary to attach another protective film onto the top chassis, the material cost of the display device can be saved.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. A display device comprising:
a display panel comprising a pixel region;
a protective film on the display panel; and
a top chassis on the display panel and defining a first open surface which exposes the pixel region and a second open surface which protrudes from an end of the first open surface.

2. The display device of claim 1, further comprising a film detaching member which is attached to the protective film and is at least partially exposed through the second open surface.

3. The display device of claim 2, wherein at least part of the film detaching member is attached to the top chassis.

4. The display device of claim 2, wherein the at least part of the film detaching member protrudes from a surface of the top chassis.

5. The display device of claim 2, wherein the first open surface is a rectangle, and the end of the first open surface is a vertex of the rectangle.

6. The display device of claim 2, wherein the first open surface is a rectangle, and the end of the first open surface is a side of the rectangle.

7. The display device of claim 2, wherein the second open surface has a substantially uniform width.

8. The display device of claim 2, wherein a width of the second open surface is reduced in a direction extending toward the first open surface.

9. The display device of claim 2, further comprising a polarizing film located between the display panel and the protective film.

10. The display device of claim 1, wherein the protective film comprises a panel protecting portion and a film detaching portion which is integrated with the panel protecting portion and protrudes from a surface of the panel protecting portion, wherein the film detaching portion is at least partially exposed through the second open surface.

11. A display device comprising:
a display panel comprising a pixel region;
a protective film on the display panel; and
a top chassis on the display panel, defining an open surface which exposes the pixel region, and comprising an openable surface which protrudes from an end of the open surface.

12. The display device of claim 11, further comprising a film detaching member which is attached to the protective film and is located under the openable surface.

13. The display device of claim 12, wherein at least part of the film detaching member is attached to the top chassis.

14. The display device of claim 12, wherein the open surface is a rectangle, and the end of the open surface is a vertex of the rectangle.

15. The display device of claim 12, wherein the open surface is a rectangle, and the end of the open surface is a side of the rectangle.

16. The display device of claim 12, further comprising a polarizing film located between the display panel and the protective film.

17. The display device of claim 11, wherein the protective film comprises a panel protecting portion and a film detaching portion which is integrated with the panel protecting portion and protrudes from a surface of the panel protecting portion, wherein the film detaching portion is disposed under the openable surface.

18. A top chassis comprising a base plate defining a first open surface which exposes a pixel region and a second open surface which protrudes from an end of the first open surface.

19. The top chassis of claim 18, wherein the first open surface is a rectangle, and the end of the first open surface is a vertex of the rectangle.

20. The top chassis of claim 18, wherein the first open surface is a rectangle, and the end of the first open surface is a side of the rectangle.
